(19) United States
(12) Patent Application Publication
(10) Pub. No.: US 2014/0007915 A1
(43) Pub. Date: Jan. 9, 2014

(54) THERMOELECTRIC GENERATOR FOR A VEHICLE AND HEAT STORAGE DEVICE FOR A THERMOELECTRIC GENERATOR OF A VEHICLE

(71) Applicant: Robert Bosch GmbH, Stuttgart (DE)

(72) Inventor: Martin Koehne, Asperg (DE)

(21) Appl. No.: 13/934,670

(22) Filed: Jul. 3, 2013

(30) Foreign Application Priority Data
Jul. 3, 2012 (DE) 10 2012 211 466.1

(51) Int. Cl. H01L 35/28

(52) U.S. Cl. CPC H01L 35/28
USPC 136/205

(57) ABSTRACT

A thermoelectric generator for a vehicle includes a generator housing arranged in an exhaust line of the vehicle and/or in a bypass to the exhaust line and at least one thermoelectric module assigned to at least one first exhaust gas contact surface. Thermal energy is transferred from the first exhaust gas contact surface to the thermoelectric module via at least one heat conduction path and at least one heat storage chamber filled with at least one heat storage material. The heat storage chamber is assigned at least one second exhaust gas contact surface from which thermal energy is configured to be transferred to the heat storage chamber. The heat storage chamber is arranged outside the heat conduction path from the first exhaust gas contact surface to the thermoelectric module. A heat storage device is provided for the thermoelectric generator of the vehicle.

This application claims priority under 35 U.S.C. §119 to patent application no. DE 10 2012 211 466.1, filed on Jul. 3, 2012 in Germany, the disclosure of which is incorporated herein by reference in its entirety.

### BACKGROUND

The disclosure relates to a thermoelectric generator for a vehicle. The disclosure furthermore relates to a heat storage device for a thermoelectric generator of a vehicle.

A thermoelectric device having a thermoelectric generator and means for limiting the temperature at the generator is described in DE 10 2006 040 853 B3. A thermoelectric generator is formed in the housing of the thermoelectric device, said generator being thermally connected on a first side thereof to a heat source and on the second side thereof, that opposite the first side, to a heat sink. A heat storage chamber, which is filled with a fusible working medium, is formed between the heat source and the thermoelectric generator. If the temperature of the heat source rises above the melting temperature of the working medium, said medium is at least partially melted, and this is supposed to enable overheating of the thermoelectric generator to be prevented. If the temperature of the heat source subsequently falls below the melting temperature of the working medium, the thermal energy liberated by the solidifying working medium is at least partially released to the thermoelectric generator. This is supposed to enable a constant temperature gradient to be maintained across the thermoelectric generator.

### SUMMARY

The disclosure provides a thermoelectric generator and a heat storage device for a thermoelectric generator of a vehicle.

The present disclosure makes it possible to equip a thermoelectric generator with at least one heat storage chamber, wherein the thermal energy of at least one exhaust gas can be conducted from at least one first exhaust gas contact surface to the at least one thermoelectric module of the thermoelectric generator via at least one heat conduction path while bypassing the at least one heat storage chamber. Expressing this in another way, one can also say that the thermal energy released by the at least one exhaust gas is deliberately not transferred via the at least one heat storage chamber to the at least one thermoelectric module. This transfer of the thermal energy of the at least one exhaust gas while bypassing the at least one heat storage chamber ensures that the thermoelectric generator has improved thermal resistance.

The conventional transfer of the thermal energy released by the at least one exhaust gas via the at least one heat storage chamber leads to a total thermal resistance which is the sum of the thermal resistance both of the at least one thermoelectric module and of the at least one heat storage chamber. In contrast, a reduced thermal resistance can be achieved by means of the present disclosure as compared with the prior art.

It is advantageous if at least one intermediate volume is situated between the at least one first exhaust gas contact surface and the at least one associated thermoelectric module in each case, wherein the at least one heat storage chamber is arranged outside the at least one intermediate volume. This ensures reliable transfer of the thermal energy liberated by the at least one exhaust gas at the at least one first exhaust gas contact surface to the at least one thermoelectric module while bypassing the at least one heat storage chamber. In this way, an advantageous reduced thermal resistance in the conversion of the thermal energy liberated by the at least one exhaust gas into electric energy is ensured.

In an advantageous embodiment, thermal energy can be transferred from the at least one heat storage chamber to the at least one associated thermoelectric module by means of at least one heat transfer contact of the thermoelectric generator, which contact is formed or can be formed. Since, as a heat transfer point between two solids, the heat transfer contact has a higher efficiency than a heat transfer point between a solid and a gas, the thermal energy temporarily stored in the at least one heat storage chamber can be output more efficiently to the at least one associated thermoelectric module. In this way, it is possible to increase the electric energy that can be obtained from the at least one heated exhaust gas by means of the thermoelectric generator.

In particular, the at least one heat transfer contact can be formed by means of at least one switchable heat-conducting connecting device of the thermoelectric generator, which device can be switched from a state in which it does not conduct heat to a state in which it conducts heat. Thus, the at least one switchable heat-conducting connecting device can be switched on specifically when the energy in the at least one heat storage chamber has been charged up. At the same time, switching the at least one switchable heat-conducting connecting device into the state in which it does not conduct heat makes it possible to prevent disadvantageous discharging of the at least one heat storage chamber.

Preferably, the at least one switchable heat-conducting connecting device of the thermoelectric generator switches from the state in which it does not conduct heat to the state in which it conducts heat at a temperature above the switching temperature, and switches from the state in which it conducts heat to the state in which it does not conduct heat at a temperature below the switching temperature. By means of the control, achievable in this way, of the at least one switchable heat-conducting connecting device, the advantages described in the preceding paragraph can be reliably achieved. In particular, the at least one switchable heat-conducting connecting device can be designed in such a way that it automatically performs the transfer from the state in which it does not conduct heat to the state in which it conducts heat at the temperature above the switching temperature, while, by virtue of its design, the switchable heat-conducting connecting device switches automatically from the state in which it conducts heat to the state in which it does not conduct heat at the temperature below the switching temperature. This eliminates the need to equip the thermoelectric generator with a controller for switching the at least one switchable heat-conducting connecting device.

For example, the at least one switchable heat-conducting connecting device of the thermoelectric generator can expand in such a way at the temperature above the switching temperature that the at least one heat transfer contact between the at least one heat storage chamber and the at least one associated thermoelectric module or an at least one heat-conducting material which makes contact with the at least one associated thermoelectric module is closed, wherein the at least one switchable heat-conducting connecting device of the thermoelectric generator contracts in such a way at the temperature below the switching temperature that the heat transfer contact is interrupted due to an air gap. As explained in greater detail below, an advantageous embodiment of this kind of the at least one switchable heat-conducting connecting device can be formed at low cost by means of simple production process steps.

In a particularly advantageous embodiment, the at least one switchable heat-conducting connecting device is formed at least partially from a shape memory alloy. In this case, at least one component part of the at least one switchable heat-conducting connecting device can automatically expand in such a way at a switching temperature equal to the associated shape memory temperature that a previously existing gap is closed.

As an alternative or in addition thereto, the at least one switchable heat-conducting connecting device can be formed in such a way as an outer casing of the at least one heat storage chamber, which is filled with at least one latent heat storage material and/or with at least one thermochemical heat storage material as the at least one heat storage material, that a phase change of the at least one latent heat storage material at the switching temperature and/or a reversible chemical reaction of the at least one thermochemical heat storage material at the switching temperature brings about a change in the shape of the outer casing of the at least one heat storage chamber. The change in shape too can be used to close a previously existing gap in such a way that the desired heat transfer contact for transferring the thermal energy to the at least one thermoelectric module is obtained.

In an advantageous development, the at least one switchable heat-conducting connecting device is coated with a catalyst which reduces a soot burn off temperature. In this way, soot deposits on the switchable heat-conducting connecting device can be prevented. Thus, reliable operation of the thermoelectric generator is still guaranteed, even during prolonged operation of the thermoelectric generator, despite said generator being exposed to soot-rich exhaust gases.

The advantages described in the above paragraphs can also be achieved by means of a corresponding heat storage device.

### BRIEF DESCRIPTION OF THE DRAWINGS

Further features and advantages of the present disclosure are explained below with reference to the figures, in which:

FIG. 1 shows a schematic illustration of a first embodiment of the thermoelectric generator;

FIG. 2 shows a schematic illustration of a second embodiment of the thermoelectric generator;

FIGS. 3a to 3d show schematic partial views intended to illustrate the operation of a third embodiment of the thermoelectric generator; and

FIG. 4 shows a schematic illustration of an embodiment of the heat storage device.

### DETAILED DESCRIPTION

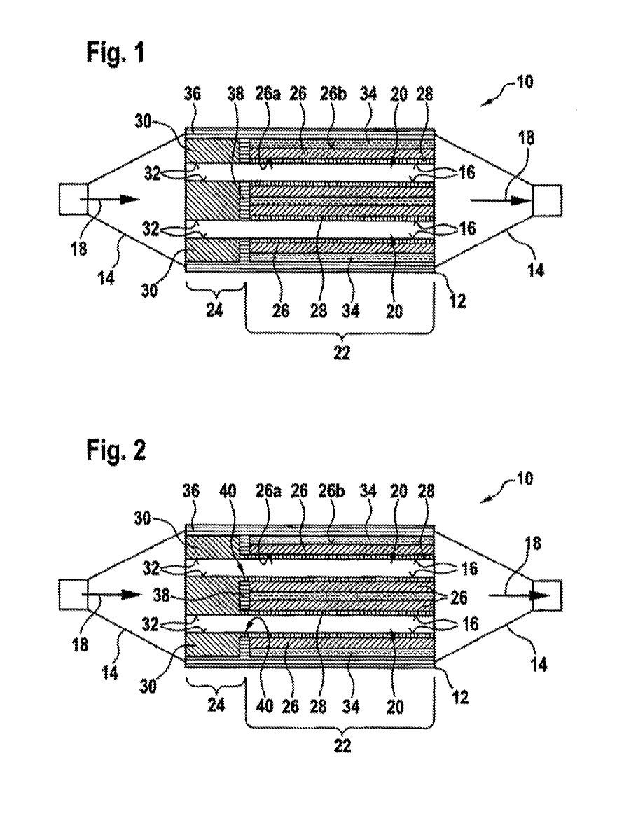

FIG. 1 shows a schematic illustration of a first embodiment of the thermoelectric generator.

The thermoelectric generator 10 illustrated schematically in FIG. 1 has a generator housing 12, which can be arranged in an exhaust line 14 of a vehicle and/or in a bypass to the exhaust line 14. The generator housing 12 can be arranged in such a way in the exhaust line 14 and/or in the bypass that at least a first exhaust gas contact surface 16 of the thermoelectric generator 10 is exposed for contacting by at least one exhaust gas 18. For example, at least one exhaust gas duct 20 can pass through the thermoelectric generator 10, through which the at least one exhaust gas 18 can be passed after arrangement of the thermoelectric generator 10 in the exhaust line 14. To enlarge the heat exchange surface thereof, the thermoelectric generator 10 can furthermore be designed with a rib structure. However, the thermoelectric generator 10 described here is not limited to a particular form.

The thermoelectric generator 10 illustrated in FIG. 1 can be divided (schematically) into a heat converter subunit 22 and a heat storage subunit 24. Preferably, the thermoelectric generator 10 can be arranged in the exhaust line 14 in such a way that the heat storage subunit 24 is situated ahead of the heat converter subunit 22. This can be interpreted to mean that, after arrangement of the generator housing 12 in the exhaust line 14 and/or in the bypass, the heat storage subunit 24 is arranged in such a way relative to the heat converter subunit 22 that the at least one exhaust gas 18 is first of all guided past the heat storage subunit 24 and makes contact with the at least one first exhaust gas contact surface 16 of the heat converter subunit 22 only after passing the heat storage subunit 24. The construction of subunits 22 and 24 will be explained in greater detail below.

The heat converter unit 22 comprises at least one thermoelectric module 26 assigned to the at least one first exhaust gas contact surface 16, wherein thermal energy released by the at least one exhaust gas 18 can be transferred from the at least one first exhaust gas contact surface 16 to the at least one thermoelectric module 26 via at least one heat conduction path. The at least one thermoelectric module 26 can be interpreted to mean a converter device which converts a flow of heat directly into electric power. For this purpose, the at least one thermoelectric module 26 preferably uses the Seebeck effect, which results in a temperature gradient in a thermoelectric material producing thermodiffusion of charge carriers. In this way, an electric potential difference between a “hot” side 26a of the thermoelectric module 26 and a “cold” side 26b of the thermoelectric module 26 can form, and this can be taken off as an electric voltage. The “hot” side 26a of the thermoelectric module 26 can be interpreted to mean a side of the thermoelectric module 26 which faces the first exhaust gas contact surface 16. In a corresponding way, the “cold” side 26b of the thermoelectric module 26 can alternatively be expressed as a side of the thermoelectric module 26 which faces away from the hot side 26a.

The heat conduction path from the at least one first exhaust gas contact surface 16 to the at least one associated thermoelectric module 26 can pass via at least one heat conduction material 28. For example, at least one intermediate volume, which is bounded in each case by a first exhaust gas contact surface 16 and by the hot side 26a of the at least one associated thermoelectric module 16, can be filled at least partially with the at least one heat conduction material 28. The at least one intermediate volume is preferably filled completely with the at least one heat conduction material 28. This ensures reliable transfer of the thermal energy liberated by the at least one exhaust gas 18 at the first exhaust gas contact surface 26 to the at least one associated thermoelectric module 26 so as to ensure a high yield of electric energy.

The heat storage subunit 24 has at least one heat storage chamber 30, which is filled at least partially with at least one heat storage material. In particular, the at least one heat storage material can be at least one latent heat storage material and/or at least one thermochemical heat storage material. The at least one heat storage chamber 30 is assigned at least one second exhaust gas contact surface 32 of the thermoelectric generator 10, which surface is exposed for contacting by the at least one exhaust gas 18, wherein thermal energy liberated can be transferred from the at least one second exhaust gas contact surface 32 to the at least one associated heat storage chamber 30. Moreover, the at least one heat storage chamber 30 is arranged outside the at least one heat conduction path. This can also be expressed by saying that thermal energy transferred from the at least one first exhaust gas contact surface 16 to the at least one thermoelectric module 26 is not transferred via the at least one heat storage chamber 30. In particular, the at least one heat storage chamber 30 can be situated outside the at least one intermediate volume bounded in each case by the at least one first exhaust gas contact surface 16 and by the hot side 26a of the at least one associated thermoelectric module 26, of the associated thermoelectric module 26.

In this way, it is possible to ensure that the at least one heat storage chamber 30 does not affect a thermal resistance during the conversion of thermal energy to electric energy. It is thus possible to achieve a reduced thermal resistance in comparison with the prior art. Whereas, conventionally, a thermal resistance during conversion of thermal energy to electric energy is the sum of the thermal resistance of the least one thermoelectric module 26 and of the at least one heat storage chamber 30, the relevant thermal resistance in the case of the advantageous thermoelectric generator 10 in FIG. 1 is (virtually) equal to the thermal resistance of the at least one thermoelectric module 26. In the case of the thermoelectric generator 10, therefore, an improved yield 10 of electric energy is obtained in comparison with a conventional generator.

By converting the waste heat of the exhaust gas 18 to electric energy, the thermoelectric generator 10 in FIG. 1 contributes to a reduction in the energy consumption and pollutant emissions of a vehicle equipped therewith. Advantages of a larger temperature gradient between sides 26a and 26b of a thermoelectric module 26 lie in high efficiency, as shown in the equation (Eq. 1):

$${η}_{max} = \frac{{T}_{H} - {T}_{C}}{{T}_{H}} + \frac{\sqrt{1 + ZT} - 1}{\sqrt{1 + ZT} + {T}_{C} / {T}_{H} ,} \qquad ( Eq . 1 )$$

where ηₘₐₓ is a maximum material efficiency, T_{H} is the temperature on the hot side 26a, T_{c} is the temperature on the cold side 26b and ZT is an integral average of the temperature gradient between sides 26a and 26b. The left-hand fraction in the equation (Eq. 1) indicates the Carnot efficiency η_{Carnot}.

It is expressly pointed out here that the thermoelectric generator 10 can still be used, even at a high exhaust gas temperature, despite its relatively low thermal resistance, without fear of damage to the at least one thermoelectric module 26. The advantageously arranged at least one heat storage chamber 30, the at least one second exhaust gas contact surface 32 of which is preferably contacted by the at least one exhaust gas 18 for the at least one first exhaust gas contact surface 16, can still prevent overheating of the at least one thermoelectric module 26, even at high/high-energy exhaust gas volume flows, e.g. those during travel on a freeway. In particular, the thermoelectric generator 10 can therefore be designed for maximum efficiency during a journey with a relatively low average speed (i.e. for a moderate exhaust gas volume flow), thereby ensuring advantageous efficiency for energy recovery, even during an urban journey, and simultaneously preventing overheating of the at least one thermoelectric module 26 during a journey on a freeway.

Owing to the advantageous interaction of the thermoelectric generator 10 with at least one heat storage chamber 30, the thermoelectric module 26 can also be designed for an advantageous thermal resistance of the heat conduction path to the thermoelectric module. Moreover, the temperature on the hot side 26a of the thermoelectric module 26 can be limited without reducing a total efficiency of the thermoelectric module 26. In particular, heat above a temperature level which could damage the thermoelectric module 26 can be converted to a temperature level which is permissible for the thermoelectric module 26.

Another advantage of the interaction of the at least one heat storage chamber 30 with the at least one thermoelectric module 26 is that the maximum permissible hot side temperature of the hot side 26a of the thermoelectric module 26 can be designed to be lower and hence the requirements on the construction and connection engineering can be reduced considerably. As a result, it is also possible to increase the reliability of the at least one thermoelectric module 26 without reducing the power yield.

Another advantage of the interaction of the at least one heat storage chamber 30 with the at least one thermoelectric module 26 is that the transient states outside the permissible temperature range of the thermoelectric generator which are often encountered in normal driving can be accommodated and exploited for energy. Transient states in the thermoelectric generator arise, for example, from overtaking maneuvers, starts from traffic signals or hilly sections of road, when the volume and temperature of the exhaust gas increase due to a significantly higher power output by the vehicle engine. By means of the technology according to the disclosure, however, the thermoelectric generator 10 is protected even in these situations, and the thermal energy present in the relatively hot exhaust gas can advantageously be used to obtain electric energy.

The at least one latent heat storage material in the at least one heat storage chamber 30 can be interpreted to mean at least one heat storage material operating on the principle of a latent heat store. Above a predetermined limiting temperature, a heat storage material of this kind undergoes a phase change and, in this way, absorbs large quantities of energy. For example, the phase change can be melting of the at least one heat storage material to absorb heat of fusion, which can be liberated again as heat of solidification at a temperature below the limiting temperature, by solidification of the at least one heat storage material.

In a particularly advantageous embodiment, the at least one heat storage chamber 30 is filled with at least one latent heat storage material (phase change material), which has a heat of fusion of more than 350 J/g and a melting temperature of less than 600° C. Preferably, the at least one latent heat storage material is a salt, a mixture of salts, a metal and/or a metal alloy. Salts, mixtures of salts, metals and metal alloys can reliably offer a high heat of fusion at a suitable melting temperature.

Filling the at least one heat storage chamber 30 with a salt or a mixture of salts furthermore offers the advantage that a relatively large quantity of energy can be stored temporarily as heat of fusion. Moreover, salts and mixtures of salts are low cost materials for latent heat storage. By forming relatively short heat transfer paths in the at least one salt, it is also possible to maintain low losses over the heat transfer path where the thermal conductivity of the at least one salt is relatively low. Moreover, more rapid heat transfer is also possible in this way.

In an advantageous development, the at least one salt can also be embedded/infiltrated into a structure consisting of a thermally conductive material, e.g. at least one metal and/or graphite. The structure consisting of the at least one thermally conductive material can be a fabric, an open-cell material and/or a foam, for example. In a particularly advantageous embodiment, the at least one salt is embedded/infiltrated into an open-cell metal foam, e.g. an aluminum foam. Thus, despite a relatively low thermal conductivity of the at least one salt, rapid heat transfer can be achieved in a simple manner.

As the at least one salt or mixture of salts, the at least one heat storage chamber 30 can contain KCl(54)-46ZnCl₂, KCl(61)-39MgCl₂, NaCl(48)-52MgCl₂, KCl(36)-64MgCl₂, NaCl(33)-67CaCl₂, MgCl₂(37)-63SrCl₂, Li₂CO₃(47)-53K₂CO₃, Li₂CO₃(44)-56Na₂CO₃, Li₂CO₃(28)-72K₂CO₃, K₂CO₃(51)-49Na₂CO₃, LiF(33)-67KF, NaF(67)-33MgF₂, NaBr(45)-55MgBr₂, LiF(20)-80LiH, KCl(25)-27CaCl₂-48MgCl₂, KCl(5)-29NaCl-66CaCl₂, KCl(13)-19NaCl-68SrCl₂, KCl(28)-19NaCl-53BaCl₂, KCl(24)-47BaCl₂-29CaCl₂, Li₂CO₃(32)-35K₂CO₃—Na₂CO₃, NaF(12)-59KF-29LiF, KCl(40)-23KF-37K₂CO₃, NaF(17)-21KF-62K₂CO₃, Li₂CO₃(35)-65K₂CO₃, Li₂CO₃(20)60-Na₂CO₃-20K₂CO₃ and/or Li₃CO(22)-16Na₂CO₃-62K₂CO₃, for example. However, the filling of the at least one heat storage chamber 30 is not limited to the salts and mixtures of salts enumerated here.

As an alternative or in addition to at least one salt, the at least one heat storage chamber 30 can also contain a metal or a metal alloy as a latent heat storage material. Filling the at least one heat storage chamber 30 with a metal and/or a metal alloy offers the advantage of high thermal conductivity of the metal filling in the at least one heat storage chamber 30 and of external surroundings of the at least one heat storage chamber 30. This heat transfer is also relatively rapid and, in particular, does not require an additional structure to improve thermal conductivity, such as a metal foam.

As the at least one metal or the at least one metal alloy, the at least one heat storage chamber 30 can contain 46.3Mg-53.7Zn, 96Zn-4Al, 34.65Mg-65.35Al, 60.8Al-33.2Cu-6.0Mg, 64.1Al-5.2Si-28.5-Cu2.2Mg, 68.5Al-5.0Si-26.5Cu, 66.92Al-33.08Cu, 83.14Al-11.7Si-5.16Mg, 87.76Al-12.24Si, 46.3Al-4.6Si-49.1Cu and/or 86.4Al-9.4Si-4.2Sb, for example. However, the suitability for use of metals/metal alloys for filling the at least one heat storage chamber 30 is not limited to the embodiments enumerated here.

All the latent heat storage materials enumerated above have a melting temperature which allows heat storage at a relatively high exhaust gas temperature. In addition, all the latent heat storage materials enumerated above have a high specific thermal storage capacity and a high heat of fusion in order to be able to temporarily store a large quantity of thermal energy, even when the dimensions of the at least one heat storage chamber 30 are relatively small. In the case of a phase change of the latent heat storage materials enumerated above, melting is congruent (undissociated). Thus, no phase separation takes place during melting or solidification, and therefore a stoichiometric composition or inhomogeneity is prevented. The respective phase changes of the latent heat storage materials enumerated above are reliably reversible and repeatable. Moreover, the latent heat storage materials have a high thermal conductivity for very low temperature gradients during heat transfer within the latent heat storage material (phase change material).

Another advantage of many latent heat storage materials enumerated is a relatively small change in volume during the phase change, something that allows the use of low-cost outer walls for the at least one heat storage chamber 30. Moreover, the latent heat storage materials mentioned do not have any pronounced tendency for an undercooled melt. Owing to the chemical stability thereof, a long service life of the latent heat storage materials is also guaranteed. In addition, the latent heat storage materials show no tendency for chemical reaction with the materials that are generally used to form an outer casing of the at least one heat storage chamber 30. The latent heat storage materials enumerated here are neither toxic nor easily flammable. The costs associated therewith are relatively low.

In a particularly advantageous embodiment, the at least one heat storage chamber 30 is at least partially filled with AlSi12 (aluminum containing 12% by mass of silicon). Such a filling ensures a relatively high heat of fusion of 560° C. Moreover, the advantages of a specific heat of the melt which is higher by over 70% than the solid can be exploited. Thus, after the complete melting of the material, more energy can be absorbed per unit of mass than in the solid. Further advantageous embodiments of latent heat storage materials are salts LiF(20)-80LiOH and NaCl(48)-52MgCl₂ and the metal alloys 60.8Al-33.2Cu-6.0Mg and 87.76Al-12.24Si.

As an alternative or in addition to at least one latent heat storage material, the at least one heat storage chamber 30 can also be filled with at least one thermochemical heat storage material. The at least one thermochemical heat storage material can be interpreted to be materials for chemical heat storage, wherein spent thermal energy can be stored temporarily by means of a reversible chemical reaction. The temporarily stored thermal energy is then liberated again by means of at least one reverse reaction.

The at least one chemical reaction can be a reversible elimination of water, for example. For this purpose, the at least one heat storage chamber 30 can contain the hydrate of calcium chloride (CaCl₂*2H₂O→CaCl₂*H₂O+H₂O), calcium hydroxide (Ca(OH)₂→CaO+2H₂O) and/or magnesium hydroxide (Mg(OH)₂→MgO+H₂O) as the thermochemical heat storage material.

A metal hydride can likewise be used as the thermochemical heat storage material in order to store thermal energy temporarily by means of the reversible decomposition. Magnesium hydride (MgH₂→Mg+H₂), in particular, is very suitable for this purpose.

The reversible decomposition of salts can also be used for heat storage, e.g. using ammonium sulfate (NH₄SO₄→NH₃+H₂O+SO₃). In addition, the reversible decomposition of metal carbonates, e.g. iron carbonate (FeCO₃→FeO+CO₂) and/or calcium carbonate (CaCO₃→CaO+CO₂) can be used for energy storage.

Moreover, thermal energy can be stored temporarily by the dilution of acids, wherein sulfuric acid (H₂SO₄+xH₂O→dilute H₂SO₄), in particular, can be used. Moreover, the reversible decomposition of alcohols, especially methanol (CH₃OH→CO+2H₂) can also be used for reversible heat storage.

All the examples enumerated here of thermochemical heat storage materials that can be used have a very high heat storage densities for chemical heat storage in their reactions, and these densities can be up to several 1000 kJ/kg. Owing to the large number of chemical reactions that can be used, at least one particularly well-suited thermochemical heat storage material can be selected for specific heat storage and temperature requirements.

The thermoelectric generator described here is also suitable for use in a vehicle with a relatively high curb weight, e.g. a commercial vehicle. Thus, high pressures may also be exerted on the at least one thermochemical heat storage material, and this increases the available choice of reversible chemical reactions that can be used. By virtue of the relatively high storage density of the thermal heat stores that can be achieved by this means, it is also possible to compensate for large load peaks. Thus, the use of the thermoelectric generator 10 allows an increase in the efficiency of commercial-vehicle-specific processes for waste heat recovery, e.g. cyclical processes (organic Rankine, steam turbocharger). Through skilful configuration of the thermoelectric generator 10, in particular of the at least one heat storage chamber 30, the proportionate amount of time for which these cyclical processes are operated at the point of maximum efficiency can be increased.

By means of the heat storage materials enumerated above, very high heat storage densities can be achieved. Moreover, the heat storage materials can also be selected to release heat at a relatively high temperature, thereby additionally increasing the efficiency of thermoelectric energy generation. Attention is drawn here, in particular, to the fact that a combination of the principle of the latent heat store and the principle of the chemical heat store can be used for temporary storage of thermal energy by means of the at least one heat storage chamber 30.

The at least one latent heat storage material and/or thermochemical heat storage material can absorb and temporarily store thermal energy at a first exhaust gas temperature, which is higher than or equal to a specific limiting temperature/heat storage temperature of the latent heat storage material and/or of the thermochemical heat storage material. At a second exhaust gas temperature of the at least one exhaust gas 18, which is less than or equal to the limiting temperature/heat storage temperature, the at least one latent heat storage material and/or thermochemical heat storage material can release this thermal energy again.

If the at least one exhaust gas 18 has a temperature which is higher than a limiting temperature of the at least one heat storage material, thermal energy can thus be absorbed and temporarily stored by means of a phase change or a reversible chemical reaction of the at least one heat storage material. In this way, it is possible to ensure that a hot side temperature of the hot side 26a of the thermoelectric module 26 remains below the maximum permissible temperature, even at relatively high exhaust gas temperatures. The at least one heat storage chamber 30 thus converts a flow of heat at a temperature higher than a maximum permissible operating temperature of the thermoelectric generator 10 into a flow of heat, the temperature of which is below the maximum permissible operating temperature of the thermoelectric generator 10. This reduction in the temperature of the flow of heat takes place continuously until the latent/thermochemical heat storage material has reached the maximum heat absorption capacity thereof. Moreover, the reduction in temperature has no effect on the amount of heat in the flow of heat. If the flow of heat is so great that there is more heat available at a reduced temperature than can flow through the thermoelectric generator 10, more of the instantaneously excess thermal energy is stored temporarily in the heat storage material. If the temperature in the thermoelectric generator 10 falls below the temperature at which heat is released from the heat storage material/limiting temperature, the heat storage material once again begins to discharge more heat into the thermoelectric generator. The thermoelectric generator 10 is thus reliably protected from damage by excessive temperatures from the exhaust gas flow.

As a supplementary feature to the components of the thermoelectric generator 10 which have been described thus far, the generator can also be designed with at least one cooling water duct 34, which is preferably routed along the at least one cold side 26b of the at least one thermoelectric module. However, the design potential of the thermoelectric generator 10 is not limited to being equipped with the at least one cooling water duct 34 or to a particular design of the latter.

The thermoelectric generator 10 illustrated schematically in FIG. 1 has an outer thermal insulation 36. In the thermoelectric generator 10, a region situated between the at least one heat storage chamber 30 and the adjacent thermoelectric module 26 and the associated intermediate volume is furthermore also filled with a thermal insulation 38. There is thus no direct heat transfer (fuel solid-body heat transfer) between the at least one heat storage chamber 30 and the at least one adjacent thermoelectric module 36. If an exhaust gas temperature of the at least one exhaust gas 18 falls below the limiting temperature, the at least one cooling heat storage chamber 30 releases the thermal energy being emitted to the at least one exhaust gas 18 via the at least one second exhaust gas contact surface 32. By means of the at least one exhaust gas 18, the thermal energy is then transmitted to the at least one first exhaust gas contact surface 16 and is then transferred to the at least one associated thermoelectric module 26. The thermal energy that is temporarily stored by means of the at least one heat storage chamber 30 can thus be converted at least partially into electric energy by the at least one thermoelectric module 26.

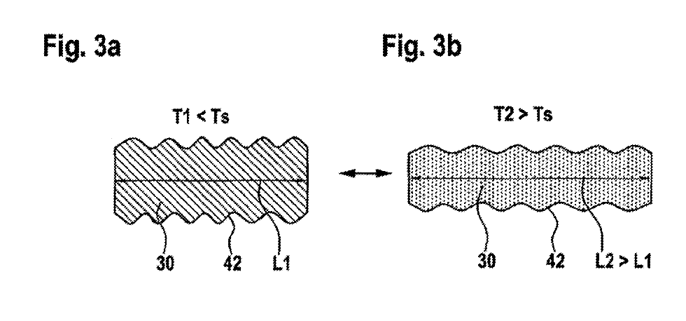

FIG. 2 shows a schematic illustration of a second embodiment of the thermoelectric generator.

The thermoelectric generator 10 illustrated schematically in FIG. 2 has the components 12, 16 and 20 to 36 already described above. In the thermoelectric generator 10 in FIG. 2, however, a region situated between the at least one heat storage chamber 30 and the intermediate volume is not completely filled with a thermal insulation 38. Instead, a heat transfer contact 40 between the at least one heat storage chamber 30 and at least one heat-conducting material 28 in the respective region is designed in such a way that thermal energy can be transferred directly from the at least one heat storage chamber 30 to the at least one associated thermoelectric module 26 by means of the at least one heat-conducting material 28 situated therebetween in each case.

This is advantageous since a heat transfer point between the solids of the at least one heat storage chamber 30 and the at least one heat-conducting material 28 has a higher efficiency than a solid/gas heat transfer point. As compared with the embodiment described above, the heat transfer contact 40 can thus replace two solid/gas heat transfer points. The thermoelectric generator 10 in FIG. 2 thus ensures a better yield of the thermal energy stored temporarily in the at least one heat storage chamber 30.

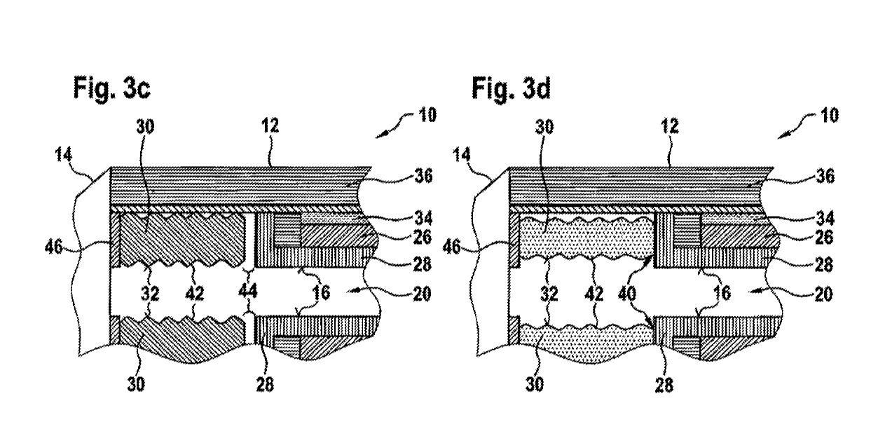

FIGS. 3a to 3d show schematic partial views intended to illustrate the operation of a third embodiment of the thermoelectric generator.

The thermoelectric generator 10 shown schematically in part by means of FIGS. 3a to 3d is designed in such a way that thermal energy can be transferred (directly or indirectly) from the at least one heat storage chamber 30 to the at least one associated thermoelectric module 26 by means of at least one heat transfer contact 40, which can be formed, of the thermoelectric generator 10. The presence of a heat transfer contact 40 which is formed or can be formed between the at least one heat storage chamber 30 and the associated thermoelectric module 26 or the at least one heat-conducting material 28 connected thereto is associated with the advantage that the temporarily stored thermal energy can be fed into the at least one thermoelectric module 26 from the at least one heat storage chamber 30 exclusively via a solid-body heat conduction path. In this way too, the abovementioned solid/gas heat transfer point can advantageously be circumvented. In this case, the feeding in of the temporarily stored thermal energy is significantly more efficient.

In particular, the at least one heat transfer contact 40 can be formed by means of at least one switchable heat-conducting connecting device 42 of the thermoelectric generator 10, wherein the switchable heat-conducting connecting device 42 can be switched from a state in which it conducts heat to a state in which it does not conduct heat. Implementing the at least one heat transfer contact 40 by means of at least one switchable heat-conducting connecting device 42 offers the advantage that the heat transfer contact 40 can be formed selectively when the limiting temperature of the at least one latent heat storage material and/or thermochemical heat storage material is exceeded. In contrast, the heat transfer contact 40 which can be formed can be interrupted selectively to the extent that the limiting temperature has not yet been undershot. In this way, it is possible to prevent a situation where thermal energy flows from the at least one heat storage chamber 30 into the at least one thermoelectric module 26 even at temperatures below the limiting temperature.

The at least one switchable heat-conducting connecting device 42 of the thermoelectric generator 10 is preferably designed in such a way that the at least one switchable heat-conducting connecting device 42 switches (automatically) from the state in which it does not conduct heat to the state in which it conducts heat at a temperature above a switching temperature Ts, and switches (automatically) from the state in which it conducts heat to the state in which it does not conduct heat at a temperature below the switching temperature Ts. By means of the automatic capacity for switching of the at least one switchable heat-conducting connecting device 42, a control device for controlling the at least one switchable heat-conducting connecting device 42 can be omitted.

In the case of the thermoelectric generator 10 in FIGS. 3a to 3d, the at least one switchable heat-conducting connecting device 42 of the thermoelectric generator 10 expands at a temperature above the switching temperature Ts. By means of the expanded switchable heat-conducting connecting device 42, the at least one heat transfer contact 40 between the at least one heat storage chamber 30 and the at least one associated thermoelectric module 26 or at least one heat-conducting material 28 which makes contact (directly or indirectly) with the at least one associated thermoelectric module 26 is closed. In contrast, the at least one switchable heat-conducting connecting device 42 of the thermoelectric generator 10 contracts in such a way at a temperature below the switching temperature Ts that the heat transfer contact 40 is interrupted due to an air gap 44.

In the embodiment in FIGS. 3a to 3d, the at least one switchable heat-conducting device 42 is formed as an outer casing of the at least one heat storage chamber 30, which is filled with the at least one latent heat storage material and/or with the at least one thermochemical heat storage material. As can be seen from FIGS. 3a and 3b, the switchable heat-conducting connecting device 42 is formed in such a way that a phase change of the at least one latent heat storage material and/or a reversible chemical reaction of the at least one thermochemical heat storage material brings about a change in the shape of the outer casing of the at least one heat storage chamber 30. This allows a low-cost design of the at least one switchable heat-conducting connecting device 42 in order to ensure that it operates in an advantageous manner.

FIG. 3a shows a switchable heat-conducting connecting device 42 designed as an outer casing of a heat storage chamber 30 in the compressed form of said device. The compressed switchable heat-conducting connecting device 42 has a first maximum length L1 at a first temperature less than a predetermined switching temperature Ts.

As can be seen from FIG. 3b, an increase in temperature to a second temperature T2 greater than the switching temperature Ts brings about an expansion of the switchable heat-conducting connecting device 42 designed as an outer casing of the heat storage chamber 30 to a second maximum length L2 greater than the first maximum length L1. This expansion of the switchable heat-conducting connecting device 42 can be used to close the at least one heat transfer contact 40. For this purpose, the at least one heat storage chamber 30 is arranged in a free space in the generator housing 12 between at least one supporting wall 46 and the at least one associated thermoelectric module 26 or the at least one heat-conducting material 28 making contact (directly or indirectly) with the at least one associated thermoelectric module 26, which has an extent in the direction of the maximum length L1 or L2 which is greater than the first maximum length L1 and less than or equal to the maximum length L2.

Thus, the presence of the switchable heat-conducting connecting device 42 in the compressed state thereof results in the presence of at least one air gap 44 between the heat storage chamber 30 and the adjacent thermoelectric module 26 or the at least one heat-conducting material 28 making contact (directly or indirectly) with the module 26 (see FIG. 3c). As can be seen from FIG. 3d, the at least one air gap 44 is bridged in such a way by the expansion of the switchable heat-conducting connecting devices 42 to at least the second maximum length L2 at a second temperature T2 greater than or equal to the switching temperature Ts that the heat transfer contact 40 is closed.

The at least one switchable heat-conducting connecting device 42 designed as the outer casing of the at least one heat storage chamber 30 can be made of nickel, for example. This is advantageous, in particular, if LiOH is used as the latent heat storage material (phase-change heat store). The switchable heat-conducting connecting device 42 as the outer casing can likewise contain the high-grade steel 1.4301 (X5CrNi18-10) for encapsulating a phase-change heat store made of 87.76Al-12.24Si and/or AlSi12. However, the materials enumerated here for forming the switchable heat-conducting connecting device 42 acting as the outer casing of the heat storage chamber 30 should be interpreted only as examples.

Attention is drawn to the fact that the above-explained design of the switchable heat-conducting connecting device 42 as the outer casing/encapsulation of the at least one heat storage chamber 30 should be interpreted only as an example. For example, the at least one switchable heat-conducting connecting device can also be formed at least partially from a shape memory alloy. In this case, a two-way shape memory alloy is particularly advantageous, wherein the switchable heat-conducting connecting device 42 has both a high-temperature and a low-temperature shape.

The switchable heat-conducting connecting device 42 formed at least partially by a shape memory alloy can be configured as a spring, for example. When the shape memory temperature is reached, the switchable heat-conducting connecting device 42 designed as a spring in this case assumes the expanded high-temperature shape thereof and can thus move a heat storage chamber 30 in the direction of the adjacent thermoelectric module 26 or the at least one associated heat-conducting material 28 in such a way that the desired heat transfer contact 40 is closed. In the case of a low-temperature shape of the at least one switchable heat-conducting connecting device 42 designed as a spring, at least one heat storage chamber 30 can be pushed back into the initial position thereof, as a result of which the heat transfer contact 42 is interrupted by an air gap 44. Formation of the at least one switchable heat-conducting connecting device 42 at least partially from a shape memory alloy thus also offers the advantages described above.

In an advantageous development, the at least one switchable heat-conducting connecting device 42, which is designed, for example, as the outer casing of the at least one heat storage chamber 30 and/or is made of a shape memory material, can be coated with a catalyst which reduces a soot burn off temperature. By means of the catalytic coating of the switchable heat-conducting connecting device 42, the burn off temperature of the soot can be reduced to such an extent that the switchable heat-conducting connecting device 42 remains (almost) free from soot, even after prolonged operation of the thermoelectric generator 10. In this way, it is possible to prevent a situation where soot is deposited on the switchable heat-conducting connecting device 42 and hence a thermal connection between the compressed switchable heat-conducting connecting device 42 and the outside environment thereof is formed by soot deposits. Cerium oxide (CeO) is suitable as a catalytic coating, for example.

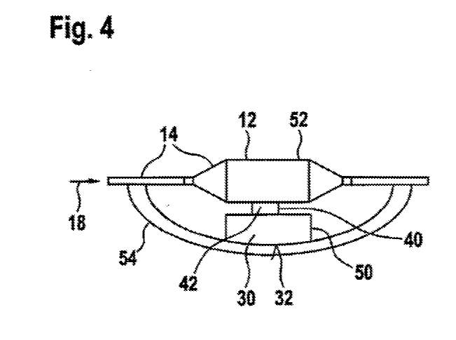

FIG. 4 shows a schematic illustration of an embodiment of the heat storage device.

The heat storage device 50 shown schematically in FIG. 4 can interact with a thermoelectric generator 52 of a vehicle. For this purpose, the heat storage device 50 can be arranged in such a way outside a generator housing 12 of the thermoelectric generator 52, in an exhaust line 14 of the vehicle and/or in a bypass 54 to the exhaust line 14, that thermal energy can be transferred from the at least one heat storage chamber 30 of the heat storage device 50 to at least one thermoelectric module 26 (not shown) of the thermoelectric generator 52 by means of at least one heat transfer contact 40, which is formed or can be formed between the heat storage device 50 and the thermoelectric generator 52. In this case too, the at least one heat storage chamber 30 is filled with at least one heat storage material. In particular, the at least one heat storage material can be at least one latent heat storage material and/or at least one thermochemical heat storage material.

In the embodiment in FIG. 4, the heat storage device 50 is integrated into a bypass 54. The advantage of such an arrangement of the heat storage device 50 is that, in this case, the exhaust gas heat passed through the bypass 54 at a relatively high temperature, which is impermissible for the thermoelectric generator 52 for example, can nevertheless also be used for the thermoelectric generator 52. For this purpose, the heat of the exhaust gas 18 passed through the bypass 54 can be stored temporarily by means of the heat storage device 50. The temporarily stored heat can then be fed into the thermal generator 52 again as soon as said generator is in the operating state thereof below the maximum design figure thereof. In this way, the electric power output of the thermoelectric generator 52 can be additionally increased.

The bypass 54 is often used to compensate for the exhaust gas temperature and/or the exhaust gas backpressure being exceeded at a high load, e.g. during a journey on a freeway. For this purpose, the bypass 54 is opened when there is a risk that the thermoelectric generator 52 will overheat due to the exhaust gas temperature and/or the exhaust gas backpressure. By means of the bypass 54, the exhaust gas flow can be routed at least partially around the thermoelectric generator 52. However, this opening of the bypass normally results in the loss of a large amount of thermal energy for the thermoelectric generator 52 and hence also for power generation. In contrast, the heat storage device 50 makes it possible also to use part of the waste heat which would otherwise be lost through the bypass 54.

In an advantageous embodiment of the heat storage device 50, the at least one heat transfer contact 40 can be formed by means of at least one switchable heat-conducting connecting device 42 of the heat storage device 50. This can be achieved by the fact that the switchable heat-conducting connecting device 42 can be switched from a state in which it does not conduct heat into a state in which it conducts heat. For this purpose, the switchable heat-conducting connecting device can, for example, be designed in such a way that the at least one switchable heat-conducting connecting device 42 switches (automatically) from the state in which it does not conduct heat to the state in which it conducts heat at a temperature above a switching temperature, and switches (automatically) from the state in which it conducts heat to the state in which it does not conduct heat at a temperature below the switching temperature. This can be achieved by designing the switchable heat-conducting connecting device 42 of the heat storage device 50 in such a way that it expands at a temperature above the switching temperature, and hence the at least one heat transfer contact 40 between the at least one heat storage chamber 30 and the thermoelectric generator 52 or the at least one thermoelectric module is closed. It is likewise possible for the at least one switchable heat-conducting connecting device 42 to be designed in such a way that it contracts at a temperature below the switching temperature, as a result of which the heat transfer contact 42 is interrupted due to an air gap (not shown).

To ensure the advantageous mode of operation of the at least one switchable heat-conducting connecting device 42 of the heat storage device 50, the at least one switchable heat-conducting connecting device can be formed at least partially from a shape memory alloy and/or can be designed as an outer casing of the at least one heat storage chamber 30. With respect to the possibility of forming the at least one switchable connecting device 42, attention is drawn to the statements made above. The at least one switchable heat-conducting connecting device 42 is preferably protected from soiling by a housing.

The heat storage device 50 illustrated schematically in FIG. 4 can be designed as a compact unit with the thermoelectric generator 52. Moreover, an outer housing of the heat storage device 50 can be formed integrally with the exhaust line 14 and/or the bypass 54.

In particular, the above-described embodiments of the thermoelectric generator 10 and 52 and of the heat storage device 50 can also be integrated into an exhaust catalyzer to form a unit. In this case, the latent heat storage material and/or the thermochemical heat storage material can be integrated into the exhaust catalyzer in such a way that the temperature of the catalytically active surface in the exhaust catalyzer can be limited by means of the at least one heat storage chamber 30. In this way, removal of catalytically active substance by an excess temperature can be prevented.

In particular, the assembly comprising an exhaust catalyzer, a thermoelectric generator 10 or 52 and/or a heat storage chamber 30/heat storage device 50 can be configured in such a way that, specifically when the catalyzer is in a high-temperature form, the heat storage chamber 30/heat storage device 50 forms a thermal contact with the catalyzer. In this way, it is possible to ensure that the catalyzer does not suffer any heat losses due to the thermoelectric generator 10 or 52 and/or the heat storage chamber 30/heat storage device 50 at low temperatures. Thus, a warm-up time before the operating temperature of the catalyzer is reached is not lengthened, despite the formation of the assembly.

What is claimed is:

1. A thermoelectric generator for a vehicle, comprising:
a generator housing arranged in one or more of an exhaust line of the vehicle and a bypass to the exhaust line in such a way that at least one first exhaust gas contact surface of the thermoelectric generator is configured to contact at least one exhaust gas;
at least one thermoelectric module assigned to the at least one first exhaust gas contact surface, thermal energy being configured to be transferred from the at least one first exhaust gas contact surface to the at least one thermoelectric module via at least one heat conduction path; and
at least one heat storage chamber filled with at least one heat storage material,
wherein the at least one heat storage chamber is assigned at least one second exhaust gas contact surface of the thermoelectric generator, the second exhaust gas contact surface being configured to contact the at least one exhaust gas,
wherein thermal energy is configured to be transferred from the at least one second exhaust gas contact surface to the at least one heat storage chamber, and
wherein the at least one heat storage chamber is arranged outside the at least one heat conduction path from the at least one first exhaust gas contact surface to the at least one thermoelectric module.

2. The thermoelectric generator according to claim 1, wherein at least one intermediate volume is situated between the at least one first exhaust gas contact surface and the at least one associated thermoelectric module in each case, and wherein the at least one heat storage chamber is arranged outside the at least one intermediate volume.

3. The thermoelectric generator according to claim 1, wherein thermal energy is configured to be transferred from the at least one heat storage chamber to the at least one associated thermoelectric module by at least one heat transfer contact of the thermoelectric generator, the contact being formed or being configured to be formed.

4. The thermoelectric generator according to claim 3, wherein the at least one heat transfer contact is configured to be formed by at least one switchable heat-conducting connecting device of the thermoelectric generator, the device being configured to be switched from a state in which it does not conduct heat to a state in which it conducts heat.

5. The thermoelectric generator according to claim 4, wherein the at least one switchable heat-conducting connecting device of the thermoelectric generator switches from the state in which it does not conduct heat to the state in which it conducts heat at a temperature above a switching temperature and switches from the state in which it conducts heat to the state in which it does not conduct heat at a temperature below the switching temperature.

6. The thermoelectric generator according to claim 5, wherein the at least one switchable heat-conducting connecting device of the thermoelectric generator expands in such a way at the temperature above the switching temperature that the at least one heat transfer contact between the at least one heat storage chamber and the at least one associated thermoelectric module or an at least one heat-conducting material which makes contact with the at least one associated thermoelectric module is closed, and the at least one switchable heat-conducting connecting device of the thermoelectric generator contracts in such a way at the temperature below the switching temperature that the heat transfer contact is interrupted due to an air gap.

7. The thermoelectric generator according to claim 6, wherein the at least one switchable heat-conducting connecting device is formed at least partially from a shape memory alloy.

8. The thermoelectric generator according to claim 6, wherein:
the at least one heat storage chamber has an outer casing into which one or more of at least one latent heat storage material and at least one thermochemical heat storage material are filled as the at least one heat storage material, and
wherein the at least one switchable heat-conducting connecting device is formed in such a way that one or more of a phase change of the at least one latent heat storage material and a reversible chemical reaction of the at least one thermochemical heat storage material brings about a change in the shape of the outer casing of the at least one heat storage chamber.

9. The thermoelectric generator according to claim 4, wherein the at least one switchable heat-conducting connecting device is coated with a catalyst that reduces a soot burn off temperature.

10. A heat storage device for a thermoelectric generator of a vehicle, comprising:
at least one heat storage chamber filled with at least one heat storage material,
wherein the heat storage device is configured to be arranged in such a way outside a housing of the thermoelectric generator, in one or more of an exhaust line of the vehicle and a bypass to the exhaust line, that thermal energy is configured to be transferred from the at least one heat storage chamber to at least one thermoelectric module of the thermoelectric generator by at least one heat transfer contact, the contact being formed or being configured to be formed between the heat storage device and the thermoelectric generator.

11. The heat storage device according to claim 10, wherein the at least one heat transfer contact is configured to be formed by at least one switchable heat-conducting connecting device of the heat storage device, the switchable heat-conducting connecting device being configured to be switched from a state in which it does not conduct heat into a state in which it conducts heat.

12. The heat storage device according to claim 11, wherein the at least one switchable heat-conducting connecting device of the heat storage device switches from the state in which it does not conduct heat to the state in which it conducts heat at a temperature above a switching temperature and switches from the state in which it conducts heat to the state in which it does not conduct heat at a temperature below the switching temperature.

13. The heat storage device according to claim 12, wherein the at least one switchable heat-conducting connecting device of the heat storage device expands in such a way at the temperature above the switching temperature that the at least one heat transfer contact is closed, and the at least one switchable heat-conducting connecting device of the heat storage device contracts in such a way at the temperature below the switching temperature that the heat transfer contact is interrupted due to an air gap.

14. The heat storage device according to claim 13, wherein the at least one switchable heat-conducting connecting device of the heat storage device is one or more of formed at least partially from a shape memory alloy and designed as an outer casing of the at least one heat storage chamber that is filled with the at least one heat storage material.

15. The heat storage device according to claim 11, wherein the at least one switchable heat-conducting connecting device is protected from soiling by a housing.
